(19) United States
(12) Patent Application Publication
(10) Pub. No.: US 2023/0111527 A1
(43) Pub. Date: Apr. 13, 2023

(54) THERMOELECTRIC COATING AND THE METHOD OF ITS APPLICATION, ESPECIALLY ON THE ELEMENTS OF THE HEAT EXCHANGER

(71) Applicant: AIC Spolka Akcyjna, Gdynia (PL)

(72) Inventors: Tomasz SIEMIENCZUK, Gdansk (PL); Wojciech GULBINSKI, Gdansk (PL); Ariel Lewandowski, Banino (PL)

(21) Appl. No.: 17/497,629

(22) Filed: Oct. 8, 2021

(51) Int. Cl. H01L 35/32; H01L 35/34

(52) U.S. Cl. CPC H01L 35/32; H01L 35/34; H01L 35/30

(57) ABSTRACT

A thermoelectric coating containing “p” and “n” semiconductor elements in the form of non-contacting layers, which are arranged alternately with each other, so that between the “p” layers there is a “n” layer, with the “p” and “n” layers “n” are connected to each other in series with conductive elements with connection terminals for the output of the generated electrical energy, and containing an electrical insulator layer, is characterized in that a layer (2a) of an electrical insulator with a thickness of at least 200 nm is applied to the substrate (1), with layers of conductive elements (3a) with a thickness of 200 nm to 5 µm, on which semiconductor layers “p” and “n” with a thickness of 50 nm to 5 µm and a width of 0.1 mm to 5 mm are applied.

### FIELD OF THE INVENTION

The subject of the invention is a thin thermoelectric coating and a method of applying it, in particular to heat exchanger elements.

### BACKGROUND

The present invention is a new approach to both the production of the thermoelectric layer, as well as its application in heat exchangers, which allows for the creation of new cogeneration devices, the so-called combined, which generate heat and electricity at the same time. This combination will not only contribute to a greater use of the generated energy for the production of heat and electricity, but also to reduce the emission of carbon dioxide and other harmful chemicals and greenhouse gases. With regard to thermoelectric phenomena, three basic principles must be considered: the Peltier effect, the Thomson effect and of course the Seebeck effect. Thermoelectric generation is basically based on the dependencies of the above-mentioned effects. The Peltier effect occurs when, by means of an electric current, heat is released on one side and absorbed on the other. The current must pass through a thermocouple or a pair of semiconductors. The Peltier coefficient shows how much heat can be transferred from one junction to another per unit charge.

The Thomson effect explains that the Seebeck coefficient is temperature dependent, so the temperature gradient can result in a gradient of the Seebeck coefficient, describes the process of cooling or heating a conductor with a flowing current and a temperature gradient in the mentioned material.

Finally, the Seebeck effect is an accumulation of electric potential in a temperature gradient and is directly related to thermoelectric generation.

Basically, when we consider two different materials having one junction at a different temperature than the other, these materials produce a thermoelectric difference according to the Seebeck effect. These two types of materials are typically p and n type semiconductors. Although thermoelectric phenomena have been known for many years, there are still very few reasonable applications regarding the Seebeck effect and electricity generation. This is mainly due to the high manufacturing costs and design constraints. The current market saturation is mainly limited to prefabricated cells. Their limitations are quite significant due to the complete absence of deformation and standardized sizes. Work on new applications is ongoing, but it is still mostly in the academic or prototype stages.

The current state of the art regarding thermoelectric coatings suggests that today there are no comprehensive solutions regarding the method of depositing thermoelectric composites and their use in devices. However, there are scientific publications on specific methods of producing semiconductor circuits for use in thermoelectric generators. Another interesting test was carried out by producing bismuth telluride layers by thermal spraying. However, due to the large inaccuracy, this method did not allow a large number of “p” - “n” semiconductor pairs, which in turn led to a low efficiency of the circuit. Due to the open structure of the semiconductor elements “p” and “n”, these systems are not safe to use, for example with water.

The patent document CN 104538542 (A) discloses a method of producing a multilayer coating composed of thermoelectric materials used in the process of manufacturing a thermoelectric assembly by means of physical vapor deposition.

Coatings based on thermoelectric materials are deposited on defined areas of the substrate by means of magnetron sputtering, where as a single layer it is less than 5 nm thick to form a thermoelectric stack. From the patent documents WO2018084727 (A1), WO2018084728 WO2018084729 (A1) a thermoelectric coating is known, the total thickness of which does not exceed 50 µm. The coating can be used on a fired tubular heat exchanger and on burner components.

### SUMMARY

The problem solved by the present invention is the development of a thermoelectric generator in the form of a thin coating applied to the elements of the device where the heat exchange takes place, almost without limiting their shape and size, which is not met by standard thermoelectric generators available on the market. In particular, the aim of the invention is to develop an efficient thermoelectric coating that will ensure the generation of electricity directly from the temperature difference without converting thermal energy into kinetic energy, which will contribute to high reliability.

This goal was achieved by developing a coating that can be applied to the heat exchanger components both on the wall of the combustion chamber and the burner housing, and by selecting semiconductor materials to maximize efficiency in the desired temperature range. A thermoelectric coating containing “p” and “n” semiconductor elements in the form of non-contacting layers, which are arranged alternately with each other, so that between the “p” layers there is a “n” layer, with the “p” and “n” layers “n” are connected to each other in series by conductive elements provided with connection terminals for outputting the generated electric energy. Thermoelectric multilayer contains an electrical insulator layer, according to the invention, characterized in that a layer of electrical insulator with a thickness of at least 200 nm is applied to the substrate, on which there are layers of conductive elements with a thickness of 200 nm up to 5 µm, on which “p” and “n” semiconductor layers are applied with a thickness of 50 nm to 5 µm and a width of 0.1 mm to 5 mm.

Lastly there are layers of conductive elements with a thickness of 200 nm to 5 µm, with the total thickness of the coating does not exceed 20 µm, and the electrical insulator layer contains Al₂O₃ or SiO₂ or MgO.

Additionally, an electrical insulator layer of at least 200 nm thickness, containing Al₂O₃ or SiO₂ or MgO, is applied over the layer of conductive elements. In addition, an intermediate layer of chromium or nickel is applied between the “p” and “n” semiconductor layers and the layer of conductive elements, the semiconductor layer is of bismuth telluride and the conductive layer is made of copper. Preferably, the interlayer is 50 nm to 200 nm thick.

Preferably, the coating is applied to the wall of the cylindrical or conical shaped heat exchanger combustion chamber and / or to the cylindrical or conical shaped housing of the burner, so that the coating layers are annular in shape. The method of applying layers of a thermoelectric coating, in particular “p” and “n” semiconductor layers and layers of conductive elements, using PVD (Physical Vapor Deposition) technology, on a cylindrical or conical shaped surface, according to the invention is characterized by in that the element on the cylindrical or conical surface of which the thermoelectric coating layers. Especially the “p” and “n” semiconductor layers and layers of conductive elements are applied, are set in rotation at a given speed, and the said layers are applied through a system of slotted screens located as close as possible rotating element ensuring its contactless rotation.

The advantages of the solution according to the present invention are the simplicity of the thermoelectric shell structure, noiselessness and no vibration during operation due to the lack of moving parts. In addition, the coating provides the generation of electricity directly from the temperature difference without converting thermal energy into kinetic energy. The generated electricity can be used to power external devices, additional electronics or even redirected to the power grid.

### BRIEF DESCRIPTION OF THE DRAWING

The invention is illustrated in the drawing in which:

FIG. 1 shows the thermoelectric coating in cross-section,

FIG. 2 shows the exposed “p” and “n” semiconductor layers of a thermocouple in the form of rings applied to the cylindrical wall of the heat exchanger combustion chamber.

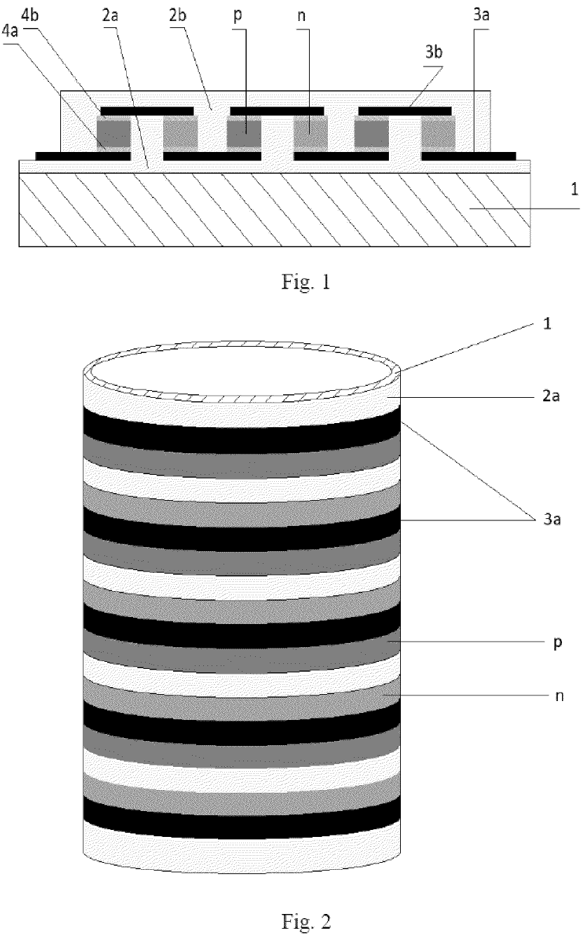

### DETAILED DESCRIPTION OF THE PREFERRED EMBODIMENTS

An exemplary thermoelectric coating includes “p” and “n” semiconductor elements in the form of non-contacting layers, which are alternately arranged in such a way that there is an “n” layer between the “p” layers, with the “p” layers “And” “n” are connected in series with the conducting elements 3a, 3b. The conductive elements 3a, 3b are provided with connection terminals for the discharge of the generated electricity.

Moreover, the conductive elements are insulated with an electric insulator layer 2a, 2b. Additionally, an intermediate layer may be applied between the “p” and “n” semiconductor layers and the layer of conductive elements 3a, 3b, 4a, 4b, for example from chromium or nickel.

The parameters of semiconductor materials are selected optimally for the intended operating temperature of the coating, which in turn allows to maximize the efficiency of the thermoelectric coating. When used, for example, in a heat exchanger, the temperature range is 100 to 150° C. The individual layers of the thermoelectric coating are produced by PVD technology, for example by evaporation, laser ablation, magnetron sputtering, filtered electric arc sputtering or electron beam excitation. The “p” and “n” semiconductor layers are obtained from the following groups of materials: bismuth tellurides, tellurium compounds, germanium compounds, silicon compounds, scutterides, inorganic clathrate compounds, chalcogenides and half-Heusler compounds. The production process of the thermoelectric coating must be carried out in a well-maintained vacuum system equipped with the necessary equipment for sputtering thin films. For good performance, it is recommended to use materials with a purity of at least 99.99% for each component applied.

The element on which the thermoelectric coating is to be applied must be properly cleaned and placed in a vacuum workstation. Further surface cleaning can be achieved by initiating a glow discharge and ion bombardment with high energy working gas atoms. On the cleaned substrate, for example the cylindrical wall of the combustion chamber of a heat exchanger, an electrical insulator layer 2a with a thickness of at least 200 nm is applied. This will allow the thermoelectric layer to be electrically independent of the substrate material. Layer

The insulation material must be homogeneous and continuous in its structure. This will ensure a high level of resistance to electrical breakdown. On the electrical insulator layer 2a, layers of low-resistivity conductive elements 3a are applied to allow the free flow of current in the form of rings with a thickness of 200 nm to 5 µm, which will form the basis for the next semiconductor layers “p” and “n”.

On the layers of conductive elements 3a, additional intermediate layers 4a, with a thickness of 50 nm to 200 nm, can be applied in the form of rings, the purpose of which is to lower the electrical resistance between the two layers where the intermediate layer is situated, by creating good electrical contact and preventing undesirable physical and chemical reactions.

Correctly located semiconductor layers made of “p” and “n” pairs, in the form of rings, with a thickness of 50 nm to 5 µm and a width of 0.1 mm to 5 mm, are applied to the intermediate layers 4a. There are many thermoelectric materials for this application which can be selected depending on the operating temperature and the desired thermoelectric performance (ZT).

Then, on the already formed semiconductor layers of the p and n pairs, additional intermediate layers 4b, with a thickness of 50 nm to 200 nm, can be applied in the form of rings, on which layers of conductive elements 3b, also in the form of rings, with a thickness of 200 nm, are applied. up to 5 µm, which should be wider than the previously applied layers of conductive elements 3a to provide a good connection point for transmitting the generated electricity.

On the layers of conductive elements 3b, if there is a need to isolate them from the environment, an electrical insulator layer 2b with a thickness of at least 200 nm is applied. Total coating thickness does not exceed 20 µm. The layers 2a, 2b of the electrical insulator are based on Al₂O₃ or SiO₂ or MgO.

With some groups of materials, there is a risk of a chemical reaction between the layers, which in turn can lead to problems such as increased electrical resistivity, impaired carrier transportation, and a reduction in the overall efficiency of the thermoelectric coating. This problem has been solved by the use of the above-mentioned intermediate layers 4a, 4b. For the bismuth telluride semiconductor layer and the copper conductive layer, it has been found that the interlayer should be chromium or nickel. The thickness of each intermediate layer must be between 50 nm and 200 nm.

Semiconductor layers “p” and “n” and layers of conductive elements 3a, 3b, on the heat exchanger elements like the cylindrical wall of the combustion chamber and the cylindrical housing of the burner, are applied using a specially designed system of slotted screens. This modification allows for the deposition of conducting and semiconductor layers in the form of rings on a cylindrical surface. The slotted screen must be placed as close as possible to the surface of the cylindrical wall, but allow free, contactless rotation. The screens must be constructed in such a way as to allow the sprayed material to pass through in an orderly manner while filtering the excessively diffused material that would lead to the application of rings with very blurred edges.

When designing and making sieves for a given substrate, the geometry and curvature of the slots as well as its total thickness should be taken into account, affecting the efficiency of filtering the beam. An element on whose cylindrical or conical surface layers of a thermoelectric coating are applied, is set in rotation with a set by speed, and said layers are applied through a system of slotted screens located as close as possible to the rotating element. The thus produced thermoelectric coating meets the expected parameters. According to Seebeck’s theory, the temperature difference on both sides of the shell causes an orderly movement of charges in the semiconductor layers contained in the thermoelectric shell. The potential difference occurs between the outer terminals due to the series connection between the elements of the semiconductor layer.

1. A thermoelectric coating comprising “p” and “n” semiconductor elements in the form of non-contacting layers, which are arranged alternately with each other, so that between “p” layers there is an “n” layer, with the “p” layers and “n” are connected to each other in series with low-resistivity conductive elements provided with connection terminals for outputting generated electrical energy, and containing an electrical insulator layer, wherein a layer (2a) of an electrical insulator with a thickness of at least 200 nm is applied to a substrate (1), on which there are layers of the low-resistivity conductive elements (3a) with a thickness of 200 nm to 5 µm, on which are applied semiconductor layers “p” and “n” in the form of rings with a thickness of 50 nm to 5 µm and a width of 0.1 mm to 5 mm, on which layers are applied of the conductive elements (3b) with a thickness of 200 nm to 5 µm, the total thickness of the coating not exceeding 20 µm, and the electrical insulator layer (2a) comprises Al₂O₃ or SiO₂ or MgO, wherein
the layers of the conductive elements (3b) is wider than the previously applied layers of comductive elements (3a) to provide a good connection point for transmitting the generated electricity, wherein
the thermoelctric coating generates electricity directly from a temperature difference without converting thermal energy into kinetic energy, and wherein insulation material of the electrical insulator is homogeneous and continuous in its structure.

2. The thermoelectric coating according to claim 1, wherein the layer (2b) of the electrical insulator with a thickness of at least 200 nm, containing Al₂O₃ or SiO₂ or MgO, is provided on the layers of the conductive elements (3b).

3. The thermoelectric coating according to claim 1, wherein a chromium or nickel intermediate layer (4a, 4b) is provided in the form of rings between the “p” and “n” semiconductor layers and the layer of conductive elements (3a, 3b), the semiconductor layer being made of bismuth telluride, and the layer of the conductive elements (3a, 3b) provided in the form of rings is made of copper.

4. The thermoelectric coating according to claim 3, wherein the intermediate layer (4a, 4b) has a thickness of 50 nm to 200 nm.

5. The thermoelectric coating according to claim 1, wherein the coating is applied to a wall of the combustion chamber of cylindrical shape or on a conical heat exchanger and/ or on a cylinder-shaped or conical-shaped housing of a burner, so that coating layers are annular in shape.

6. A method of applying layers of a thermoelectric coating, especially “p” and “n” semiconductor layers and layers of conductive elements, using PVD technology, on a surface of cylindrical or conical shape, wherein the element on the cylindrical or conical surface of which layers are the thermoelectric coating, in particular the “p” and “n” semiconductor layers and layers of conductive elements, are rotated at a predetermined speed, and said layers are applied through a system of slotted screens located as close as possible to the rotating element.
